(19) United States
(12) Patent Application Publication
(10) Pub. No.: US 2017/0096066 A1
(43) Pub. Date: Apr. 6, 2017

(54) INVERTER WITH THERMAL CONDUCTIVITY INTERFACE MATERIAL AND HYBRID VEHICLE TO WHICH THE SAME IS APPLIED

(71) Applicants: Hyundai Motor Company, Seoul (KR); Kia Motors Corporation, Seoul (KR); Infineon Technologies AG, Neubiberg (DE)

(72) Inventors: Hyun-Koo Lee, Seoul (KR); Andreas Grassmann, Regensburg (DE)

(21) Appl. No.: 15/246,047

(22) Filed: Aug. 24, 2016

(30) Foreign Application Priority Data
Oct. 1, 2015 (KR) 10-2015-0138540

(51) Int. Cl. B60L 1/02; B60K 6/20; H02M 7/44; H05K 7/20; B60L 11/18; B60L 11/02

(52) U.S. Cl. CPC B60L 1/02; B60L 11/1809; B60L 11/02; H02M 7/44; H05K 7/209; B60K 6/20; B60Y 2200/92; Y10S 903/903

(57) ABSTRACT

A hybrid vehicle including a hybrid power control unit (HPCU) is provided. The HPCU includes a power module having chips disposed therein, each of which generates heat during operation, a coolers that cools the heat from the power module. Additionally chip soldering interface material (SIM)s that bond the chips and the power module are provided to form interior solder layers. Further, a cooler Soldering Interface Material (SIM)s bonds the power module and the coolers to form an exterior solder layers. Consequently, improvements in cooling performance and a reduction in cost are achieved, without a variation in applied thickness and a pump-out phenomenon caused when using a TIM having low thermal conductivity.

### CROSS-REFERENCE TO RELATED APPLICATION

This application claims priority to Korean Patent Application No. 10-2015-0138540, filed on Oct. 1, 2015, which is incorporated herein by reference in its entirety.

### BACKGROUND

Field of the Invention

The present invention relates to an inverter and, more particularly, to a hybrid vehicle having an inverter with thermal conductivity interface material, capable of achieving improved cooling performance and a reduction in cost through bonding between a cooler and a power module.

Description of Related Art

Generally, hybrid power control units (HPCU) mounted to hybrid vehicles or electric vehicles, which are motor-driven vehicles, are used to increase the input voltages to reduce currents applied to the systems and improve the motor performance. In particular, the HPCUs are a critical technology for hybrid vehicles and electric vehicles. Typically, an HPCU is configured together with an insulated gate bipolar transistor (IGBT) and a cooler, which are core components and contribute to the majority of the costs. In particular, the IGBT is referred to as a power module, and the semiconductor devices (chips) of the power module generate a significant amount of heat when they operate due to the high internal voltage and significant current thereof. Accordingly, the rated currents of the semiconductor devices and diodes may be reduced to improve the cooling performance of the power module. Further, the sizes of the chips may be reduced. Therefore, cost of manufacturing the chips may be reduced and the power module may be operated stably.

For example, in the technical field of the HPCU, there is a need for techniques related to the shape or bonding of the cooler that improve the cooling performance of the power module, in addition to a single-sided or double-sided cooling method for the cooler and the power module. A thermal interface material (TIM) bonding method is a representative example of cooler bonding techniques. In the TIM bonding method, thermal grease is used to bond a cooler to a power module. Exemplary cooling methods include, a single-sided cooling case, having a cooler bonded to one surface of a power module using thermal grease. Alternatively, a double-sided cooling mold type cooling method includes coolers bonded to both surfaces of a power module using thermal grease. Accordingly, since the thermal grease is interposed between the power module and the cooler(s), the cooling performance of the power module is improved by the thermal conductivity of the thermal grease. Thus, the manufacturing cost of the power module is reduced while the HPCU has improved thermal performance.

However, since the TIM bonding method is applied to both of the single-sided cooling case type cooling method and the double-sided cooling mold type cooling method, it has limited performance characteristics. First, since the TIM has a low thermal conductivity of about 0 to 5 K/Wm and the HPCU (power module cooler) has a thermal performance of about 20 to 30%, the overall cooling performance of the HPCU is low. Secondarily, a pump-out phenomenon, in which the TIM is consumed due to the repeated thermal contraction and expansion of the power module during the operation thereof, occurs, resulting in the lack of TIM. Thirdly, since the TIM application between the cooler and the power module is difficult the power module may have non-uniform thermal conductivity due to a variation in thickness of the TIM. Further, the power module may have poor reliability due to partial high temperature. Fourthly, the double-sided cooling mold type cooling method, in which the TIM is applied to at least two to four surfaces of the power module, has the limited characteristics as in the single-sided cooling case type cooling method.

The above information disclosed in this section is merely for enhancement of understanding of the background of the invention and therefore it may contain information that does not form the prior art that is already known in this country to those of ordinary skilled in the art.

### SUMMARY

The present invention provides an inverter with thermal conductivity interface material, capable of achieving an improvement in cooling performance and a reduction in cost in a hybrid vehicle. Further, the invention provides absence of a variation in applied thickness and a pump-out phenomenon, by bonding a cooler and a power module using a SIM having high thermal conductivity, compared to using a TIM having low thermal conductivity., In particular, a reduction in the cost of an HPCU and an increase in the competitive power by the improved cooling performance of the power module may be achieved.

In accordance with one aspect of the present invention, an inverter with thermal conductivity interface material may include a power module having chips therein, each of which generates heat when the chip operates, a cooler configured to cool the heat from the power module, a chip SIM that bonds the chips and the power module to form an interior solder layer, and a cooler SIM that bonds the power module and the cooler to form an exterior solder layer. The chip SIM may have a greater melting temperature than the cooler SIM.

The power module may be a single-sided cooling power module in which the cooler is bonded to a first surface of the power module by the cooler SIM. The single-sided cooling power module may include a first DBC plate bonded to the chips by the chip SIM, a case coupled with the first DBC plate such that the cooler is bonded to an exposed exterior surface of the first DBC plate by the cooler SIM, and a filler that occupies (e.g., fills) an interior space of the case. The filler may be a gel. A base plate may be disposed between the exposed exterior surface of the first DBC plate and the cooler. The cooler SIM may be used to bond the exposed exterior surface of the first DBC plate and the base plate and may bond the base plate and the cooler.

The power module may be a double-sided cooling power module in which coolers are bonded to both surfaces of the power module by cooler SIMs. The double-sided cooling power module may include first and second DBC plates that define a space therebetween adjacent to each other, and a filler mold that fills the space between the first and second DBC plates. The chips may be respectively bonded to the adjacent surfaces of the first and second DBC plates by chip SIMs. The coolers may be respectively bonded to the exposed exterior surfaces of the first and second DBC plates by the cooler SIMs. The filler mold may be an epoxy molding compound (EMC). A spacer may be disposed between the first and second DBC plates, the adjacent surfaces of which may be bonded to the chips by the chip SIMs. The chip SIMs may be used to bond the chips and the spacer and to bond the spacer and the second DBC plate.

In accordance with another exemplary embodiment, a hybrid vehicle may include an internal combustion engine, a motor generator configured to generate electric power while being actuated with electricity, a battery configured to supply electric power while being charged, and an HPCU that includes a single-side cooling power module. The single-side cooling power module may have a first DBC plate bonded to first and second chips by a chip SIM, a case coupled with the first DBC plate such that a first cooler is bonded to an exposed exterior surface of the first DBC plate by a cooler SIM, and a filler that occupies an interior space of the case.

In accordance with an exemplary embodiment of the present invention, a hybrid vehicle may include an internal combustion engine, a motor generator configured to generate electric power while being actuated with electricity, a battery configured to supply electric power while being charged, and an HPCU. The HPCU may include a double-side cooling power module, which has first and second DBC plates that define a space therebetween adjacent to each other, and a filler mold that occupies the space between the first and second DBC plates. The first and second chips may be respectively bonded to the adjacent surfaces of the first and second DBC plates by chip SIMs. Further, the first and second coolers may be respectively bonded to the exposed exterior surfaces of the first and second DBC plates by cooler SIMs.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is an exemplary view illustrating a single-sided cooling case type inverter with thermal conductivity interface material according to a first exemplary embodiment of the present invention;

FIG. 2 is an exemplary view illustrating a double-sided cooling mold type inverter with thermal conductivity interface material according to a second exemplary embodiment of the present invention;

FIG. 3A is an exemplary view illustrating an example of a hybrid vehicle to which the inverter with thermal conductivity interface material according to an exemplary embodiment of the present invention; and

FIG. 3B-3C are exemplary views illustrating an HPCU according to an exemplary embodiment of the present invention.

### DETAILED DESCRIPTION

Reference will now be made in detail to various exemplary embodiments of the present invention, examples of which will be described below in more detail with reference to the accompanying drawings. The present invention may, however, be embodied in different forms and should not be construed as limited to the embodiments set forth herein. On the contrary, the invention is intended to cover not only the exemplary embodiments, but also various alternatives, modifications, equivalents and other embodiments, which may be included within the spirit and scope of the invention as defined by the appended claims. Throughout the disclosure, like reference numerals refer to like parts throughout the various figures and exemplary embodiments of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, in order to make the description of the present invention clear, unrelated parts are not shown and, the thicknesses of layers and regions are exaggerated for clarity. Further, when it is stated that a layer is “on” another layer or substrate, the layer may be directly on another layer or substrate or a third layer may be disposed therebetween.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

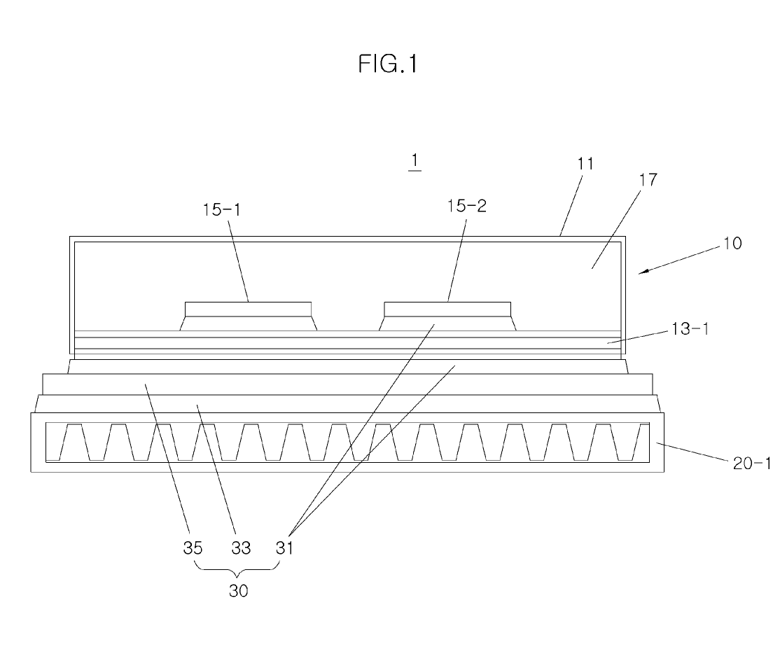

FIG. 1 is an exemplary view illustrating a single-sided cooling case type inverter with thermal conductivity interface material according to an exemplary embodiment of the present invention. As illustrated in the drawing, the single-sided cooling case type inverter 1, may include a single-sided cooling power module 10, a first cooler 20-1, and a SIM bonding section 30. The single-sided cooling case type inverter 1 may be an HPCU, or may be configured together with the HPCU.

In particular, the single-sided cooling power module 10 may include a case 11 that opens at one surface of the rectangular surfaces thereof, a first direct bonded cooper plate (DBC) plate 13-1 which covers the opened surface of the case 11, first and second chips 15-1 and 15-2 which are bonded to the first DBC plate 13-1 within the interior space of the case 11, and a filler 17 which fills the interior space of the case 11. Further, the case 11 may have a circular or triangular shape or a polygonal shape to expose the first DBC plate 13-1 is exposed to one side thereof. A copper substrate may be applied to the first DBC plate 13-1. The first and second chips 15-1 and 15-2 may be a semiconductor chip. The filler 17 may be a gel made such that a colloidal solution is thickened above a certain concentration to be solidified in a compact reticular form.

In some exemplary embodiments, the first cooler 20-1 may be attached to the case 11 of the single-sided cooling power module 10, and may be configured to absorb and dissipate heat generated from the single-sided cooling power module 10 by an increase in area through the corrugated portion thereof. For example, the first cooler 20-1 may be attached to the exposed exterior surface of the first DBC plate 13-1 when the case 11 has a rectangular cross-section in which the first DBC plate 13-1 is coupled to one surface of the case 11.

The SIM bonding section 30 may include chip SIMs 31 that bond the internal components of the single-sided cooling power module 10, a cooler SIM 33 which has a lower melting temperature than the chip SIMs 31 to thereby bond the first cooler 20-1 to the single-sided cooling power module 10, and a base plate 35 disposed between the first cooler 20-1 and the single-sided cooling power module 10. For example, the chip SIMs 31 may be used to bond the first DBC plate 13-1 and the first and second chips 15-1 and 15-2 and to bond the first DBC plate 13-1 and the base plate 35, thereby being directly applied to the single-sided cooling power module 10. Conversely, the cooler SIM 33 may be used to bond the base plate 35 and the first cooler 20-1, thereby being directly applied to the first cooler 20-1. In other words, the chip SIMs 31 may be directly applied to the single-sided cooling power module 10, to form interior solder layers, and the cooler SIM 33 may be directly applied to the first cooler 20-1, to form an exterior solder layer.

In particular, the cooler SIM 33 may have a lower melting temperature than the chip SIMs 31. The lower melting temperature may prevent the solder layer (the chip SIM 31) disposed between the base plate 35 and the first DBC plate 13-1 and the solder layer (the chip SIM 31) disposed between the first DBC plate 13-1 and the first and second chips 15-1 and 15-2 from being re-melted due to the high temperature generated when the first cooler 20-1 is soldered to the base plate 35. Additionally, the base plate 35 may be made of a material except for ceramic which prevents soldering.

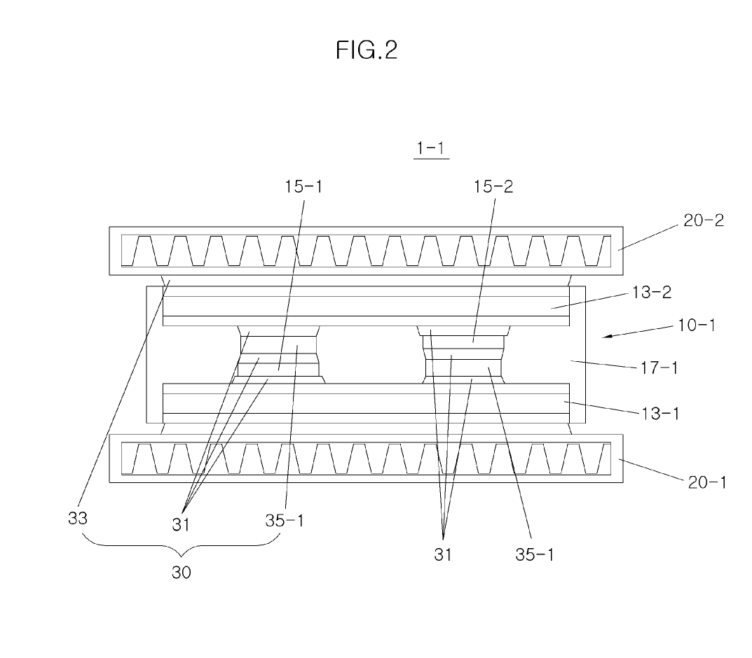

FIG. 2 is an exemplary view that illustrates a double-sided cooling mold type inverter with thermal conductivity interface material according to an exemplary embodiment of the present invention. As illustrated in the drawing, the double-sided cooling mold type inverter 1-1, may include a double-sided cooling power module 10-1, first and second coolers 20-1 and 20-2, and a SIM bonding section 30. The double-sided cooling mold type inverter 1-1 may be an HPCU, or may be coupled together with the HPCU.

In particular, the double-sided cooling power module 10-1 may include first and second DBC plates 13-1 and 13-2 which are separated from each other at a distance and adjacent to each other. Further first and second chips 15-1 and 15-2 may be bonded to the first DBC plate 13-1, and a filler mold 17-1 may enclose the interior space defined by the first and second DBC plates 13-1 and 13-2 while surrounding the first and second DBC plates 13-1 and 13-2 having one surface of each of the first and second DBC plates 13-1 and 13-2 is exposed to the exterior. The first and second chips 15-1 and 15-2 may be a semiconductor chip. The filler mold 17-1 may uses an epoxy molding compound (EMC).

The respective first and second coolers 20-1 and 20-2 may be attached to the exposed exterior surfaces of the first and second DBC plates 13-1 and 13-2 of the double-sided cooling power module 10-1. Each of the first and second coolers 20-1 and 20-2 may configured to absorb and dissipate heat generated from the double-sided cooling power module 10-1 by an increase in area through the corrugated portion thereof. For example, the first cooler 20-1 may be attached to the exposed exterior surface of the first DBC plate 13-1, and the second cooler 20-2 may be attached to the exposed exterior surface of the second DBC plate 13-2. In particular, the first and second coolers 20-1 and 20-2 may have the same components.

The SIM bonding section 30 may include chip SIMs 31 that bond the internal components of the double-sided cooling power module 10-1, cooler SIMs 33 which may have a lower melting temperature than the chip SIMs 31 to thereby bond both of the first and second coolers 20-1 and 20-2 to the double-sided cooling power module 10-1. A spacer 35-1 may be bonded into the double-sided cooling power module 10-1 by the chip SIMs 31. For example, the chip SIMs 31 may be used to bond the first DBC plate 13-1 and the first and second chips 15-1 and 15-2 and to bond the first and second chips 15-1 and 15-2, the spacer 35-1, and the second DBC plate 13-2, thereby being directly applied to the double-sided cooling power module 10-1.

Conversely, the cooler SIMs 33 may be used to bond the first cooler 20-1 and the exposed exterior surface of the first DBC plate 13-1 and to bond the second cooler 20-2 and the exposed exterior surface of the second DBC plate 13-2, thereby being directly applied to the respective first and second coolers 20-1 and 20-2. In other words, the chip SIMs 31, directly applied to the double-sided cooling power module 10-1, may form interior solder layers, and the cooler SIMs 33, which are directly applied to the respective first and second coolers 20-1 and 20-2, may form exterior solder layers.

In particular, each of the cooler SIMs 33 may have a lower melting temperature than the chip SIMs 31. Accordingly, the solder layers (the chip SIMs 31) disposed between the spacer 35-1, the second DBC plate 13-2, and the first and second chips 15-1 and 15-2, and the solder layer (the chip SIM 31) disposed between the first DBC plate 13-1 and the first and second chips 15-1 and 15-2 may be prevented from being re-melted. For example, the high temperature generated when the respective first and second coolers 20-1 and 20-2 are soldered to the first and second DBC plates 13-1 and 13-2 may cause re-melting. In addition, the spacer 35-1 may be made of a material except for ceramic to prevent soldering.

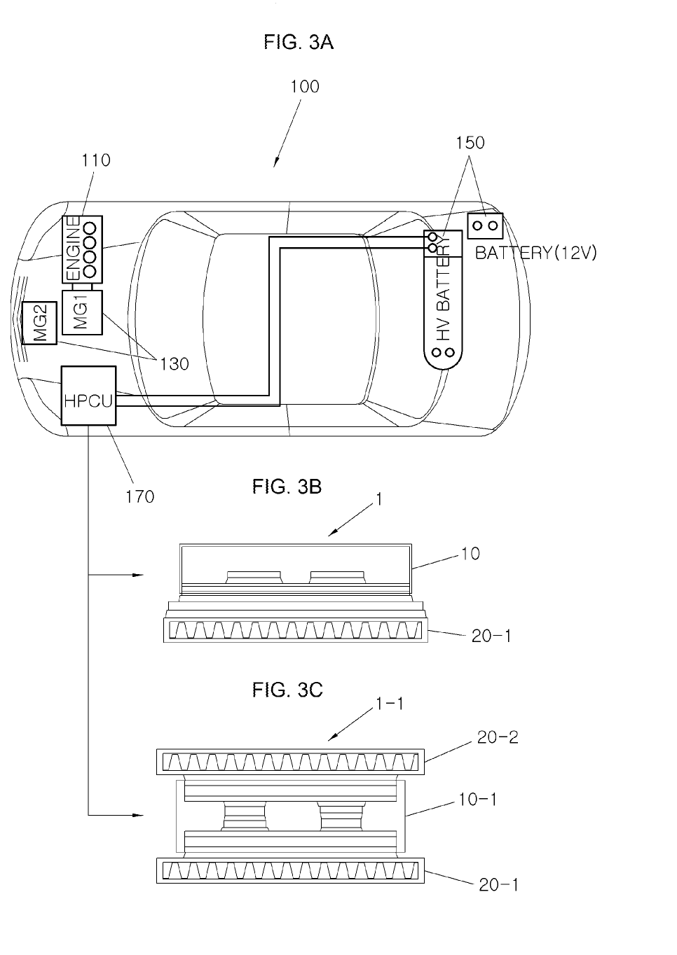

Moreover, FIG. 3A is an exemplary view that illustrates an example of a hybrid vehicle to which the inverter with thermal conductivity interface material is applied. As illustrated in the drawing, the hybrid vehicle 100, may include an engine 110, a motor generator 130 configured to generate electric power while being actuated with electricity, a battery 150 configured to supply electric power while being charged, and an HPCU 170 configured to increase an input voltage to reduce a current applied to a system. The engine 110 may be an internal combustion engine which uses gasoline, diesel, or LPG as fuel, and allows the hybrid vehicle 100 to be propelled. The motor generator 130 may be configured as two motor generators, and may allow the hybrid vehicle 100 to be propelled. The battery 150 may be configured as a high-voltage battery and a low-voltage battery.

The HPCU 170 may include an inductor configured to increases an input voltage, a capacitor configured to smooth an input current, a high-voltage connector that may provide an interface configured to supply an alternating current (AC) output voltage to the motor generator 130, and the single-sided cooling power module 10 described in FIG. 1 or the double-sided cooling power module 10-1 described in FIG. 2, configured to convert a direct current (DC) voltage into a 3-phase AC voltage. In particular, the HPCU 170 may include the single-sided or double-sided cooling power module 10 or 10-1 using the soldering process instead of using existing thermal grease processes. Accordingly, the cooling performance of the power module may have improved efficiency even though the power module generates a substantial amount of heat due to the increased internal voltage and increased current thereof. Therefore, the overall performance of the hybrid vehicle 100 may be significantly improved based on the efficient cooling performance of the HPCU 170.

As described above, the hybrid vehicle according to an exemplary embodiment as shown in FIGS. 3B and 3C, include the HPCU 170 that may include the power module 10 or 10-1 having the chips 15-1 and 15-2 therein. Each chip may be configured to generate heat during operation. The cooler(s) 20-1 or/and 20-2 may be configured to reduce the heat from the power module 10 or 10-1. The chip SIMs 31 may bond the chips 15-1 and 15-2 and the power module 10 or 10-1 to form the interior solder layers. The cooler SIM(s) 33 may bond the power module 10 or 10-1 and the cooler(s) 20-1 or/and 20-2 may form the exterior solder layers. Consequently, cooling performance may be improved and the cost may be reduced, without a variation in applied thickness and a pump-out phenomenon caused when using a TIM having low thermal conductivity. In particular, a reduction in cost of the HPCU 70 and realize high competitive power by the improved cooling performance of the HPCU 170 may be achieved.

In accordance with the exemplary embodiments of the present invention, the HPCU include the cooler and the power module bonded using the SIM having high thermal conductivity that provides several advantages. First, the HPCU has an improved cooling performance of about 30%, compared to using the TIM having low thermal conductivity. Secondarily, the size and cost of the chip may be reduced by the improved cooling performance of the power module, and thus the HPCU may have an increased competitive power. Thirdly, since the TIM is not consumed due to the pump-out even though the power module may be repeatedly operated, and the HPCU may be operated stably. Fourthly, the compensation for the variation in height of the power module may be performed by the exterior solder layer disposed between the power module and the cooler. The process of adjusting the variation in height of the power module may be simplified together with the simplification of the process management for adjusting the variation in height of the power module. In addition, since the HPCU includes the cooler and the power module which are bonded using the SIM and is mounted to the vehicles, the HPCU may be more easily applied to existing hydrogen fuel cell vehicles in addition to the electric and hybrid vehicles.

While the present invention has been particularly shown and described with respect to the referenced exemplary embodiments, it will be apparent to those skilled in the art that various changes and modifications may be made without departing from the spirit and scope of the invention as defined in the following claims. The exemplary embodiments should be considered in a descriptive sense only and not for purposes of limitation.

What is claimed is:

1. An inverter with thermal conductivity interface material, comprising:
a power module having chips disposed therein, each of which is configured to generate heat when each chip operates;
a cooler configured to cool the heat from the power module;
a chip soldering interface material (SIM) that bonds the chips and the power module to form an interior bonding layer; and
a cooler Soldering Interface Material (SIM) that bonds the power module and the cooler to form an exterior bonding layer.

2. The inverter of claim 1, wherein the chip SIM has a higher melting temperature than the cooler SIM.

3. The inverter of claim 1, wherein the power module is a single-sided cooling power module in which the cooler is bonded to one surface of the power module by the cooler SIM.

4. The inverter of claim 3, wherein the single-sided cooling power module includes a first direct bonded cooper(DBC) plate bonded to the chips by the chip SIM;
a case coupled with the first DBC plate wherein the cooler is bonded to an exposed exterior surface of the first DBC plate by the cooler SIM; and
a filler filling an interior space of the case.

5. The inverter of claim 4, wherein the filler is a gel.

6. The inverter of claim 4, wherein a base plate is disposed between the exposed exterior surface of the first DBC plate and the cooler, and the cooler SIM is used to bond the exposed exterior surface of the first DBC plate and the base plate and to bond the base plate and the cooler.

7. The inverter of claim 1, wherein the power module is a double-sided cooling power module in which coolers are bonded to both surfaces of the power module by cooler SIMs.

8. The inverter of claim 7, wherein the double-sided cooling power module includes:
first and second DBC plates that define a space therebetween positioned adjacent to each other, and
a filler mold filling the space between the first and second DBC plates, wherein the chips are respectively bonded to the adjacent surfaces of the first and second DBC plates by chip SIMs, and the coolers are respectively bonded to exposed exterior surfaces of the first and second DBC plates by the cooler SIMs.

9. The inverter of claim 8, wherein the filler mold is an epoxy molding compound (EMC).

10. The inverter of claim 8, wherein a spacer is disposed between the first and second DBC plates, the adjacent surfaces of which are bonded to the chips by the chip SIMs, and the chip SIMs are used to bond the chips and the spacer and to bond the spacer and the second DBC plate.

11. A hybrid vehicle, comprising:
an internal combustion engine;
a motor generator configured to generate electric power while being actuated with electricity disposed within the internal combustion engine;
a battery configured to supply electric power while being charged; and
an hybrid power control unit (HPCU) including:
a single-side cooling power module, having a first direct bonded cooper DBC) plate bonded to first and second chips by a chip soldering interface material (SIM), a case coupled with the first DBC plate having a first cooler bonded to an exposed exterior surface of the first DBC plate by a cooler SIM, and
a filler filling an internal space of the case.

12. The hybrid vehicle of claim 11, wherein the chip SIM has a higher melting temperature than the cooler SIM.

13. A hybrid vehicle, comprising:
an internal combustion engine;
a motor generator configured to generate electric power while being actuated with electricity disposed within the internal combustion engine;
a battery configured to supply electric power while being charged; and
an hybrid power control unit (HPCU) including:
a double-side cooling power module, which includes first and second direct bonded cooper DBC) plates that define a space therebetween adjacent to each other; and
a filler mold configured to fill the space between the first and second DBC plates, first and second chips being respectively bonded to adjacent surfaces of the first and second DBC plates by chip soldering interface material SIM), first and second coolers being respectively bonded to exposed exterior surfaces of the first and second DBC plates by cooler SIMs.

14. The hybrid vehicle of claim 13, wherein the chip SIM has a higher melting temperature than the cooler SIM.
